(19) United States
(12) Patent Application Publication
(10) Pub. No.: US 2025/0240868 A1
(43) Pub. Date: Jul. 24, 2025

(54) Printed circuit board assembly

(71) Applicant: Cooler Master Technology Inc., Taipei City (TW)

(72) Inventors: Yi-Cheng Lin, Taipei City (TW); Chao-Nan Hsiao, Taipei City (TW); Jui-Tse Yin, Taipei City (TW)

(21) Appl. No.: 19/033,428

(22) Filed: Jan. 21, 2025

(30) Foreign Application Priority Data
Jan. 19, 2024 (TW) 113200685

(51) Int. Cl. H05K 1/02

(52) U.S. Cl. CPC H05K 1/0204

(57) ABSTRACT

A printed circuit board assembly may include one or more electrical components, a substrate, and one or more heatsinks. Each one or more electrical components includes a body and one or more terminal pins. Each one or more terminal pins includes a main pin portion and solder end portion. The substrate includes a top surface, bottom surface, and plurality of through-holes. Each plurality of through-holes receives each one or more terminal pins therethrough. When each plurality of through-holes receives each one or more terminal pins therethrough, the body extends from the top surface and the solder end portion extends from the bottom surface. Each one or more heatsinks is configured to respectively absorb a heat and dissipate the heat from each one or more electrical components. Each one or more heatsinks is thermally coupled to the solder end portion of each one or more terminal pins and the bottom surface.

### RELATED APPLICATIONS

This US application claims the benefit of priority to Taiwan application no. 113200685, filed on Jan. 19, 2024, of which is incorporated herein by reference in its entirety.

### TECHNICAL FIELD

The present disclosure is related to heat dissipation of printed circuit boards in general and more particularly but not limited to printed circuit board assemblies having SMD heatsinks mounted thereto.

### BACKGROUND OF THE INVENTION

With increasing processing speed and performance of electronic devices, the amount of heat generated during operation of an electronic device has increased. The heat generation increases the temperature of the electronic device and, if the heat cannot be dissipated effectively, the reliability and performance of the electronic device is reduced.

Certain components of the electronic device may generate more heat than other components. When a component reaches an extreme temperature that surpasses the component's safe operating range, its lifetime will not only be greatly reduced, but the component may fail. A defective heat-generating component may mean an entire printed circuit board assembly (PCBA) of the electronic device will need to be replaced.

To prevent overheating of an electronic device, PCB heat sinks may be used to efficiently absorb and dissipate the heat generated by the heat-producing components and, thereby ensure the standard operation of the PCBA and the electronic device. PCB heat sinks may be attached to the heat-generating component by clip-on and push-pin mounting. Thermal interface materials (TIMs) may be used to fill in air gaps between mating surfaces, improving heat transfer therebetween.

However, with demand for smaller and smaller electronic devices continuing to increase, heat from the heat-generating components have become more problematic. Available space for fans, large heat sinks, or spacing between components to prevent heat diffusion around a board has decreased. The smaller spaces have increased the temperature of the heat-generating components. Also, for clip-on and push-pin mounting, disposition may be dependent upon corresponding available holes, limiting placement, or holes will need to be drilled, increasing installation time and risks for damage to the PCBA. Furthermore, improper application, thickness, and pressure, may lead to suboptimal thermal performance of the TIMs. Also, natural degradation over time and pump-out may lead the TIMs to no longer effectively transfer heat away from the heat source.

### SUMMARY OF THE INVENTION

The present disclosure provides a PCBA including SMD heat sinks to prevent overheating of heat-producing components of an electronic device.

In some aspects, the techniques described herein relate to a printed circuit board assembly, including one or more electrical components, a substrate, and one or more heatsinks. Each one or more electrical components includes a body and one or more terminal pins. Each one or more terminal pins extend outward from a side of the body. Each one or more terminal pins includes a main pin portion and a solder end portion. The substrate includes a top surface, a bottom surface, and a plurality of through-holes. The bottom surface is opposite the top surface and each plurality of through-holes respectively form openings through the top surface and the bottom surface. Each plurality of through-holes is configured to receive the one or more terminal pins therethrough. When each plurality of through-holes receives the one or more terminal pins therethrough, the body extends from the top surface and the solder end portion extends from the bottom surface. Each one or more heatsinks is configured to respectively absorb a heat and dissipate the heat from each one or more electrical components. Each one or more heatsinks is respectively thermally coupled to the solder end portion of each one or more terminal pins and the bottom surface.

In some aspects, the techniques described herein relate to a printed circuit board assembly, wherein the substrate further includes an insulation gap surrounding each plurality of through-holes, and wherein each one or more heatsinks is mounted to the bottom surface at the insulation gap.

In some aspects, the techniques described herein relate to a printed circuit board assembly, wherein the one or more heatsinks includes a gap cut-out, the gap cut-out is mounted at the insulation gap abutting at least one solder end portion of the one or more terminal pins.

In some aspects, the techniques described herein relate to a printed circuit board assembly, wherein the one or more heatsinks includes a first heatsink. The first heatsink includes a W-like shape having a first arm portion, a second arm portion, a center arm portion, and a base portion. The base portion includes a first end, a second end, and a center. The first arm portion extends from the first end, the second arm portion extends from the second end, and the center arm portion extends from the center. The first heatsink is mounted at the insulation gap surrounding the solder end portion of each one or more terminal pins. In some aspects, the techniques described herein relate to a printed circuit board assembly, wherein the second arm portion includes a hook end. The hook end is opposite the second end and extends from the second arm portion toward the center arm portion. In some aspects, the techniques described herein relate to a printed circuit board assembly, wherein the gap cut-out includes one or more gap cut-outs. The second arm portion includes the one or more gap cut-outs.

In some aspects, the techniques described herein relate to a printed circuit board assembly, wherein the first heatsink further includes a first left end protrusion and a first right end protrusion, and wherein the bottom surface includes a first left receiving recess and a first right receiving recess. The first left receiving recess is configured to receive the first left end protrusion therein and the first right receiving recess is configured to receive the first right end protrusion therein when the first heatsink is mounted to the bottom surface. In some aspects, the techniques described herein relate to a printed circuit board assembly, wherein the one or more terminal pins surrounded by the first heatsink include round-shaped terminal pins.

In some aspects, the techniques described herein relate to a printed circuit board assembly, wherein the one or more heatsinks includes a second heatsink. The second heatsink includes an equilateral quadrilateral frame shape having a second opening. The second opening of the second heatsink is mounted at the insulation gap surrounding the solder end portion of each one or more terminal pins. In some aspects, the techniques described herein relate to a printed circuit board assembly, wherein the second heatsink further includes a second left end protrusion and a second right end protrusion, and wherein the bottom surface includes a second left receiving recess and a second right receiving recess. The second left receiving recess is configured to receive the second left end protrusion therein and the second right receiving recess is configured to receive the second right end protrusion therein when the second heatsink is mounted to the bottom surface. In some aspects, the techniques described herein relate to a printed circuit board assembly, wherein the one or more terminal pins surrounded by the second heatsink include flat-shaped terminal pins.

In some aspects, the techniques described herein relate to a printed circuit board assembly, further including a copper foil. The copper foil is coupled to the bottom surface and the copper foil is between each one or more heatsinks and the bottom surface.

In some aspects, the techniques described herein relate to a printed circuit board assembly, further including a solder mask. The solder mask is coupled to the copper foil.

In some aspects, the techniques described herein relate to a printed circuit board assembly, wherein each one or more heatsinks includes a solder. The solder is disposed between the bottom surface and each one or more heatsinks to mount each one or more heatsinks to the bottom surface. In some aspects, the techniques described herein relate to a printed circuit board assembly, wherein each one or more heatsinks includes a surface mounted device.

### BRIEF DESCRIPTION OF DRAWINGS

Unless specified otherwise, the accompanying drawings illustrate aspects of the innovative subject matter described herein. Referring to the drawings, wherein like reference numerals indicate similar parts throughout the several views, several examples of printed circuit board assemblies incorporating aspects of the presently disclosed principles are illustrated by way of example, and not by way of limitation.

FIG. 1A illustrates a perspective view of a printed circuit board assembly, according to one embodiment of the present disclosure.

FIG. 1B illustrates an exploded view of the printed circuit board assembly of FIG. 1A, according to one embodiment of the present disclosure.

FIG. 2A illustrates a partial perspective view of the printed circuit board assembly of FIG. 1A, having line A-A′ cross-section, according to one embodiment of the present disclosure.

FIG. 2B illustrates the cross-section along line A-A′ of the printed circuit board assembly of FIG. 2A, according to one embodiment of the present disclosure.

FIG. 3 illustrates an enlarged view of the printed circuit board assembly of FIG. 2B, according to one embodiment of the present disclosure.

FIG. 4 illustrates a partial cross-section view of an alternative printed circuit board assembly, according to one embodiment of the present disclosure.

### DETAILED DESCRIPTION

The following describes various principles related to printed circuit board assemblies by way of reference to specific examples of electrical components, substrates, and heatsinks, including specific arrangements and examples of mounted heatsinks embodying innovative concepts. More particularly, but not exclusively, such innovative principles are described in relation to selected examples of mounted heatsinks, and well-known functions or constructions are not described in detail for purposes of succinctness and clarity. Nonetheless, of the disclosed principles can be incorporated in various other embodiments of different mounted heatsinks to achieve any of a variety of desired outcomes, characteristics, and/or performance criteria.

Thus, mounted heatsinks having attributes that are different from those specific examples discussed herein can embody of the innovative principles, and can be used in applications not described herein in detail. Accordingly, embodiments of mounted heatsinks not described herein in detail also fall within the scope of this disclosure, as will be appreciated by those of ordinary skill in the relevant art following a review of this disclosure.

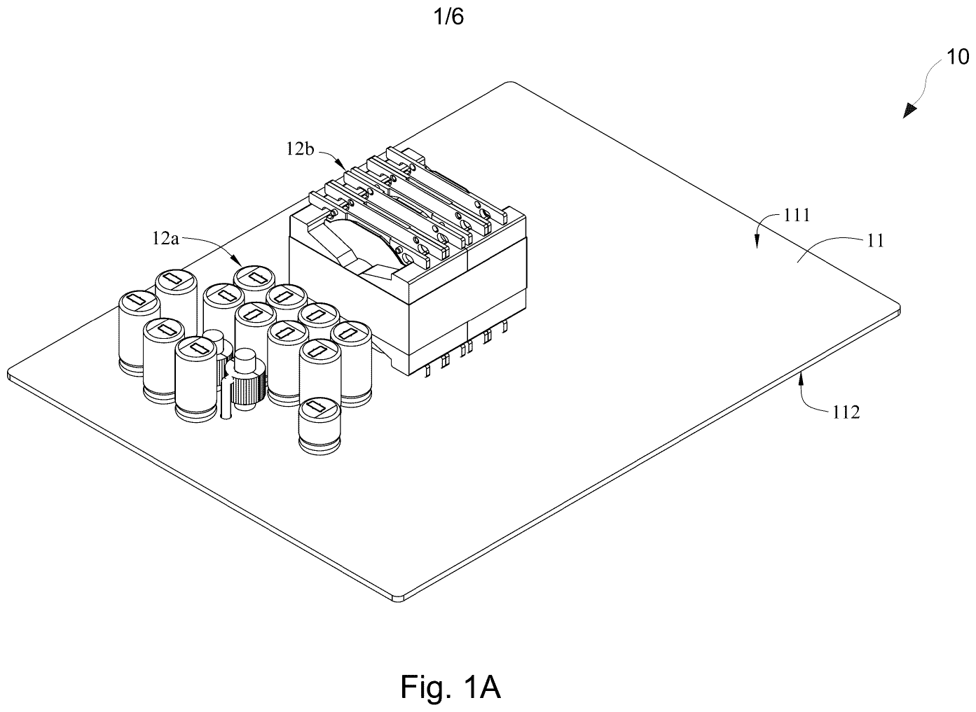

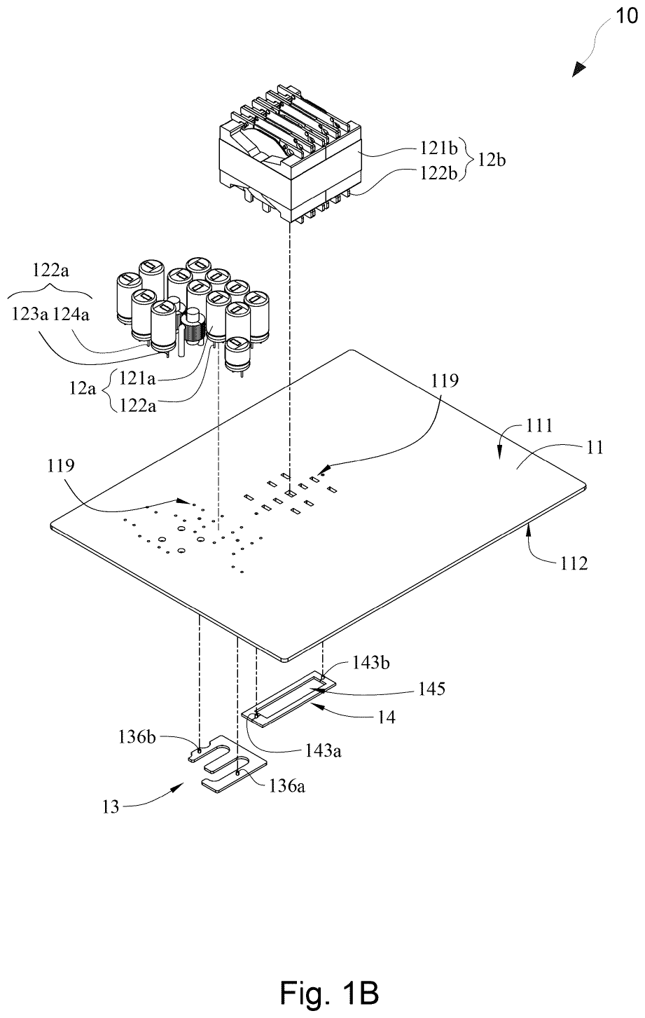

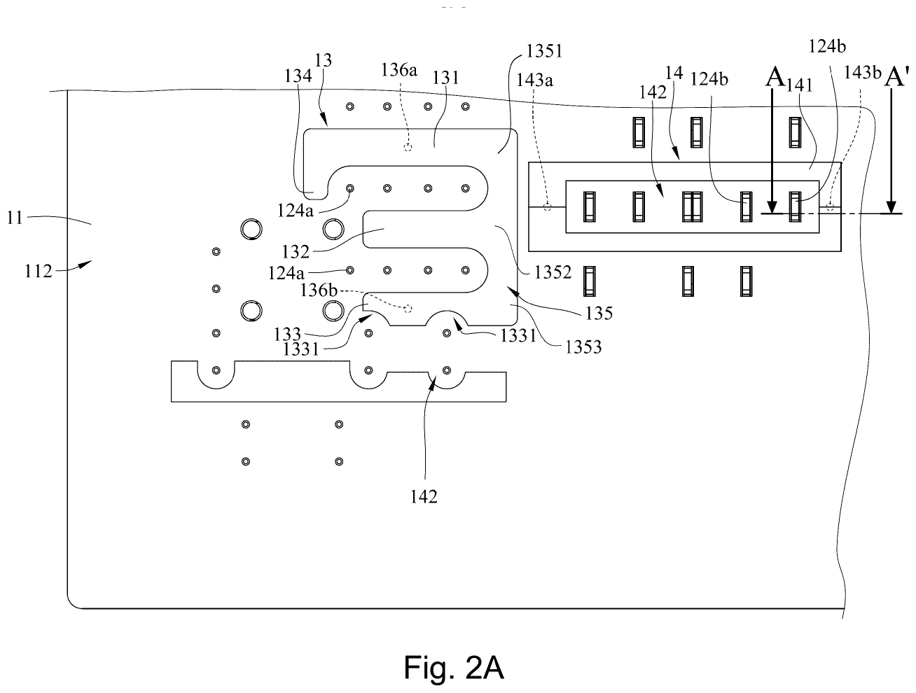

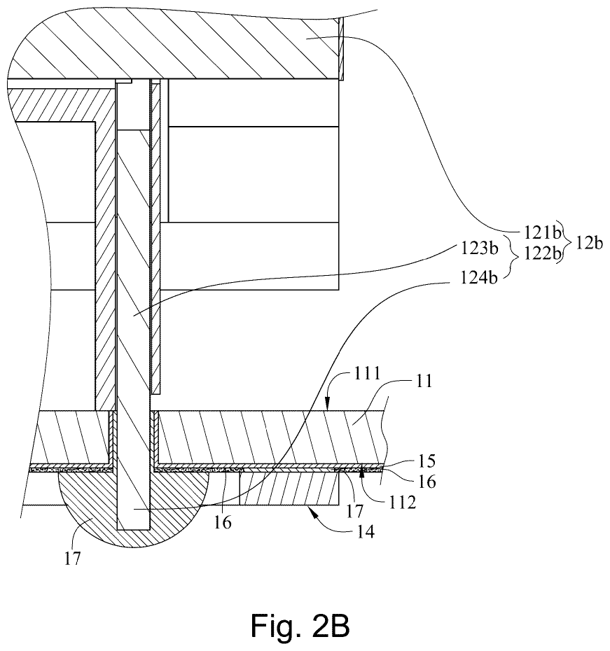

FIGS. 1A, 1B and 2A include at least one embodiment of a printed circuit board assembly 10. The printed circuit board assembly 10 includes one or more electrical components 12a/12b, a substrate 11, and one or more heatsinks 13/14. Each one or more electrical components 12a/12b includes a body 121a/121b and one or more terminal pins 122a/122b. Each one or more terminal pins 122a/122b extend outward from a side of the body 121a/121b. Each one or more terminal pins 122a/122b includes a main pin portion 123a/123b and a solder end portion 124a/124b. The substrate 11 includes a top surface 111, a bottom surface 112, and a plurality of through-holes 119. The bottom surface 112 is opposite the top surface 111 and each plurality of through-holes 119 respectively form openings through the top surface 111 and the bottom surface 112. Each plurality of through-holes 119 is configured to receive the one or more terminal pins 122a/122b therethrough. When each plurality of through-holes 119 receives the one or more terminal pins 122a/122b therethrough, the body 121a/121b extends from the top surface 111 and the solder end portion 124a/124b extends from the bottom surface 112. Each one or more heatsinks 13/14 is configured to respectively absorb a heat and dissipate the heat from each one or more electrical components 12a/12b. Each one or more heatsinks 13/14 is respectively thermally coupled to the solder end portion 124a/124b of each one or more terminal pins 122a/122b and the bottom surface 112. In some embodiments, the one or more electrical components 12a/12b include transformers and other electrical components. Examples of PCB transformers include power transformers, RF transformers, switch mode transformers and the like.

In some embodiments, the substrate 11 further includes an insulation gap 142 surrounding each plurality of through-holes 119, and wherein each one or more heatsinks 13/14 is mounted to the bottom surface 112 at the insulation gap 142.

In some embodiments, the one or more heatsinks 13/14 includes a gap cut-out 1331, the gap cut-out 1331 is mounted at the insulation gap 142 abutting at least one solder end portion 124a/124b of the one or more terminal pins 122a/122b. In some embodiments, the gap cut-out 1331 includes an arc-shaped gap cut-out 1331.

In some embodiments, the one or more heatsinks 13/14 includes a first heatsink 13. The first heatsink 13 includes a W-like shape having a first arm portion 133, a second arm portion 131, a center arm portion 132, and a base portion 135. The base portion 135 includes a first end 1353, a second end 1351, and a center 1352. The first arm portion 133 extends from the first end 1353, the second arm portion 131 extends from the second end 1351, and the center arm portion 132 extends from the center 1352. The first heatsink 13 is mounted at the insulation gap 142 surrounding the solder end portion 124a/124b of each one or more terminal pins 122a/122b. In some embodiments, the second arm portion 131 includes a hook end 134. The hook end 134 is opposite the second end 1351 and extends from the second arm portion 131 toward the center arm portion 132. In some embodiments, the gap cut-out 1331 includes one or more gap cut-outs 1331. The second arm portion 131 includes the one or more gap cut-outs 1331.

In some embodiments, the first heatsink 13 further includes a first left end protrusion 136a and a first right end protrusion 136b, and wherein the bottom surface 112 includes a first left receiving recess and a first right receiving recess. The first left receiving recess is configured to receive the first left end protrusion 136a therein and the first right receiving recess is configured to receive the first right end protrusion 136b therein when the first heatsink 13 is mounted to the bottom surface 112. In some embodiments, the one or more terminal pins 122a/122b surrounded by the first heatsink 13 include round-shaped terminal pins. In some embodiments, the first heatsink 13 further includes a first left end receiving recess (not shown) and a first right end receiving recess (not shown), and wherein the bottom surface 112 includes a first left protrusion (not shown) and a first right protrusion (not shown).

In some embodiments, the one or more heatsinks 13/14 includes a second heatsink 14. The second heatsink 14 includes an equilateral quadrilateral frame shape having a second opening 145. The second opening 145 of the second heatsink 14 is mounted at the insulation gap 142 surrounding the solder end portion 124a/124b of each one or more terminal pins 122a/122b. In some embodiments, the second heatsink 14 further includes a second left end protrusion 143a and a second right end protrusion 143b, and wherein the bottom surface 112 includes a second left receiving recess and a second right receiving recess. The second left receiving recess is configured to receive the second left end protrusion 143a therein and the second right receiving recess is configured to receive the second right end protrusion 143b therein when the second heatsink 14 is mounted to the bottom surface 112. In some embodiments, the one or more terminal pins 122a/122b surrounded by the second heatsink 14 include flat-shaped terminal pins. In some embodiments, the second heatsink 14 further includes a second left end receiving recess (not shown) and a second right end receiving recess (not shown), and wherein the bottom surface 112 includes a second left protrusion (not shown) and a second right protrusion (not shown).

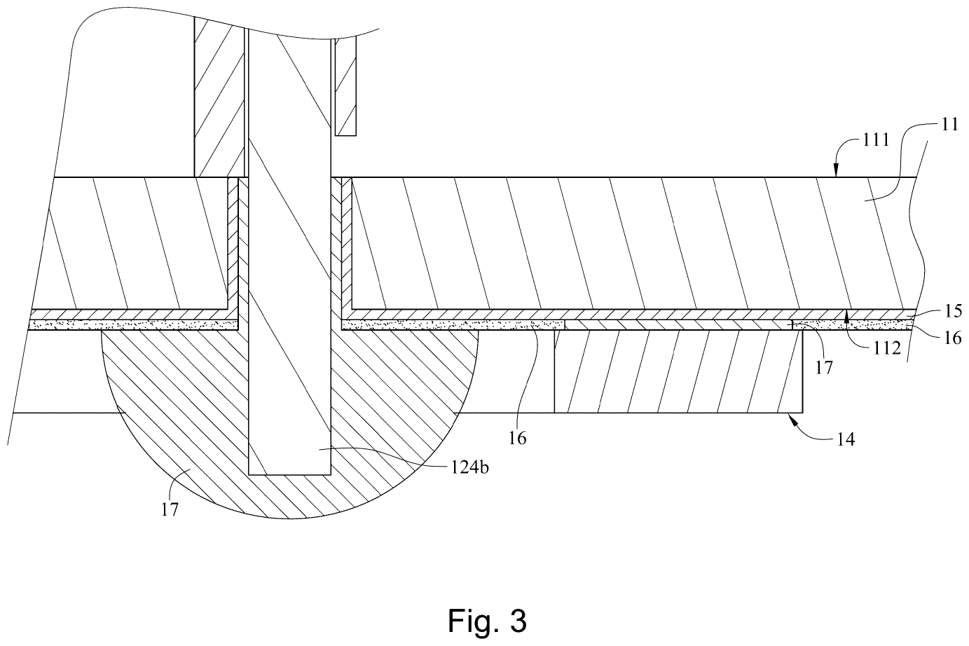

FIGS. 2B and 3 include at least one embodiment of the printed circuit board assembly 10. In some embodiments, the printed circuit board assembly 10 further includes a copper foil 15. The copper foil 15 is coupled to the bottom surface 112 and the copper foil 15 is between each one or more heatsinks 13/14 and the bottom surface 112. In some embodiments, the printed circuit board assembly 10 further includes a solder mask 16. The solder mask 16 is coupled to the copper foil 15. In some embodiments, each one or more heatsinks 13/14 includes a solder 17. The solder 17 is disposed between the bottom surface 112 and each one or more heatsinks 13/14 to mount each one or more heatsinks 13/14 to the bottom surface 112. In some embodiments, the solder 17 is disposed between the copper foil 15 and each one or more heatsinks 13/14 to mount each one or more heatsinks 13/14 to the bottom surface 112. Each one or more heatsinks 13/14 is respectively thermally coupled to the solder end portion 124a/124b of each one or more terminal pins 122a/122b via the solder 17, the copper foil 15, and the substrate 11. Thus, the heat is transferred through each one or more terminal pins 122a/122b to the copper foil 15 and substrate 11 to the solder 17 and throughout each one or more heatsinks 13/14. In some embodiments, each one or more heatsinks 13/14 includes a surface mounted device.

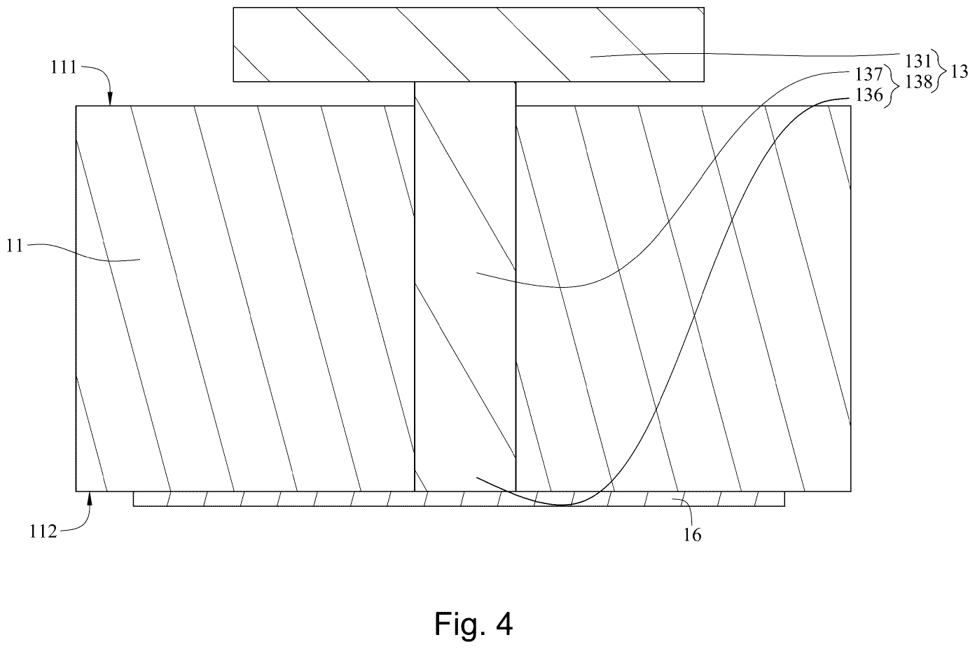

FIG. 4 includes at least one embodiment of an alternative printed circuit board assembly. The alternative printed circuit board assembly may be similar in some respects to the printed circuit board assembly 10 of FIGS. 1A, 1B, 2A, 2B and 3 therefore may be best understood with reference thereto where like numerals designate like components not described again in detail. The only differences between the printed circuit board assembly 10 of FIGS. 1A, 1B, 2A, 2B and 3 and the alternative printed circuit board assembly of FIG. 4 is that when each plurality of through-holes 119 receives the one or more terminal pins 138 of the one or more electrical components 13 therethrough, the body 137 extends from the top surface 111 and the solder end portion 136 does not extend from the bottom surface 112. In the alternative printed circuit board assembly 10, the solder mask 16 covers the opening through the bottom surface 112 and the solder end portion abuts the solder mask 16.

The present disclosure provides a printed circuit board assembly 10 including SMD heat sinks to prevent overheating of the one or more electrical components 12a/12b of electronic devices. The left end protrusions 136a, 143a, right end protrusion 136b, 143b, left receiving recesses, and right receiving recesses efficiently and conveniently position each one or more heatsinks 13/14 to the bottom surface 112 of the substrate 11. Also, the SMD heat sinks are mounted to the bottom surface 112 via soldering. Thus, disposition of the one or more heatsinks 13/14 is not dependent upon corresponding available holes, freeing up placement options, and eliminating the need to drill holes, which in turn decreases risks for damage to the printed circuit board assembly. Also, mounting strength and heat transfer is increased via the solder 17. Thus, improper application, thickness, and pressure of TIMs, leading to suboptimal thermal performance and the natural degradation over time and pump-out of the TIMs to no longer effectively transfer heat away from the heat source is eliminated. Moreover, heat transfer is further enhanced via coupling of the copper foil 15. Lastly, SMD heat sinks are flat heatsinks. Thus, the printed circuit board assembly 10 including SMD heat sinks are compatible with the trend for smaller and smaller electronic devices. Heat is dissipated effectively, and reliability and performance of electronic device having the printed circuit board assemblies 10 of the present disclosure is provided.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean than one of the element that it introduces.

1. A printed circuit board assembly, comprising:
one or more electrical components, each one or more electrical components includes a body and one or more terminal pins, each one or more terminal pins extend outward from a side of the body, each one or more terminal pins includes a main pin portion and a solder end portion;
a substrate, the substrate including a top surface, a bottom surface, and a plurality of through-holes, the bottom surface opposite the top surface, each plurality of through-holes respectively form openings through the top surface and the bottom surface, each plurality of through-holes configured to receive the one or more terminal pins therethrough, when each plurality of through-holes receives the one or more terminal pins therethrough, the body extends from the top surface and the solder end portion extends from the bottom surface; and
one or more heatsinks, each one or more heatsinks configured to respectively absorb a heat and dissipate the heat from each one or more electrical components, each one or more heatsinks respectively thermally coupled to the solder end portion of each one or more terminal pins and the bottom surface.

2. The printed circuit board assembly of claim 1, wherein the substrate further comprises an insulation gap surrounding each plurality of through-holes, and wherein each one or more heatsinks is mounted to the bottom surface at the insulation gap.

3. The printed circuit board assembly of claim 2, further comprising a copper foil, the copper foil coupled to the bottom surface, the copper foil between each one or more heatsinks and the bottom surface.

4. The printed circuit board assembly of claim 3, further including a solder mask, the solder mask coupled to the copper foil.

5. The printed circuit board assembly of claim 2, wherein each one or more heatsinks includes a solder, the solder is disposed between the bottom surface and each one or more heatsinks to mount each one or more heatsinks to the bottom surface.

6. The printed circuit board assembly of claim 5, wherein each one or more heatsinks includes a surface mounted device.

7. The printed circuit board assembly of claim 2, wherein the one or more heatsinks includes a gap cut-out, the gap cut-out is mounted at the insulation gap abutting at least one solder end portion of the one or more terminal pins.

8. The printed circuit board assembly of claim 7, wherein the one or more heatsinks includes a first heatsink, the first heatsink includes a W-like shape having a first arm portion, a second arm portion, a center arm portion, and a base portion, the base portion includes a first end, a second end, and a center, the first arm portion extends from the first end, the second arm portion extends from the second end, and the center arm portion extends from the center, the first heatsink mounted at the insulation gap surrounding the solder end portion of each one or more terminal pins.

9. The printed circuit board assembly of claim 8, wherein the second arm portion includes a hook end, the hook end opposite the second end, the hook end extending from the second arm portion toward the center arm portion.

10. The printed circuit board assembly of claim 8, wherein the gap cut-out includes one or more gap cut-outs, the second arm portion includes the one or more gap cut-outs.

11. The printed circuit board assembly of claim 8, wherein the first heatsink further includes a first left end protrusion and a first right end protrusion, and wherein the bottom surface includes a first left receiving recess and a first right receiving recess, the first left receiving recess configured to receive the first left end protrusion therein and the first right receiving recess configured to receive the first right end protrusion therein when the first heatsink is mounted to the bottom surface.

12. The printed circuit board assembly of claim 8, wherein the one or more terminal pins surrounded by the first heatsink include round-shaped terminal pins.

13. The printed circuit board assembly of claim 2, wherein the one or more heatsinks includes a second heatsink, the second heatsink includes an equilateral quadrilateral frame shape having a second opening, the second opening of the second heatsink mounted at the insulation gap surrounding the solder end portion of each one or more terminal pins.

14. The printed circuit board assembly of claim 13, wherein the second heatsink further includes a second left end protrusion and a second right end protrusion, and wherein the bottom surface includes a second left receiving recess and a second right receiving recess, the second left receiving recess configured to receive the second left end protrusion therein and the second right receiving recess configured to receive the second right end protrusion therein when the second heatsink is mounted to the bottom surface.

15. The printed circuit board assembly of claim 13, wherein the one or more terminal pins surrounded by the second heatsink include flat-shaped terminal pins.
